(19) United States
(12) Patent Application Publication
(10) Pub. No.: US 2012/0329177 A1
(43) Pub. Date: Dec. 27, 2012

(54) SPIN-TORQUE MAGNETORESISTIVE STRUCTURES WITH BILAYER FREE LAYER

(75) Inventors: David William Abraham, Croton-on-Hudson, NY (US); Guohan Hu, Yorktown Heights, NY (US); Jonathan Zanhong Sun, Shrub Oak, NY (US); Daniel Christopher Worledge, Poughquag, NY (US)

(73) Assignee: International Business Machines Corporation, Armonk, NY (US)

(21) Appl. No.: 13/602,749

(22) Filed: Sep. 4, 2012

Related U.S. Application Data
(62) Division of application No. 12/489,987, filed on Jun. 23, 2009.

(51) Int. Cl. H01L 43/10

(52) U.S. Cl. 438/3; 257/E43.005

(57) ABSTRACT

Magnetoresistive structures, devices, memories, and methods for forming the same are presented. For example, a magnetoresistive structure includes a ferromagnetic layer, a ferrimagnetic layer coupled to the ferromagnetic layer, a pinned layer and a nonmagnetic spacer layer. A free side of the magnetoresistive structure comprises the ferromagnetic layer and the ferrimagnetic layer. The nonmagnetic spacer layer is at least partly between the free side and the pinned layer. A saturation magnetization of the ferromagnetic layer opposes a saturation magnetization of the ferrimagnetic layer. The nonmagnetic spacer layer may include a tunnel barrier layer, such as one composed of magnesium oxide (MgO), or a nonmagnetic metal layer.

### CROSS-REFERENCE TO RELATED APPLICATION

This application is a Divisional of U.S. patent application Ser. No. 12/489,987, filed on Jun. 23, 2009, the disclosure of which is incorporated herein by reference.

### TECHNICAL FIELD

The field relates generally to magnetoresistive structures, spintronics, memory and integrated circuits. More particularly, the invention relates to spin-torque magnetoresistive structures and devices including spin-torque based magnetoresistive random access memory (MRAM).

### BACKGROUND

Magnetoresistive random access memories (MRAMs) combine magnetic components with standard silicon-based microelectronics to achieve non-volatile memory. For example, silicon based microelectronics comprise electronic devices such as transistors, diodes, resistors, interconnect, capacitors or inductors. Transistors comprise field effect transistors and bipolar transistors. Other MRAMs may comprise magnetic components with other semiconductor components, for example, components comprising gallium arsenide (GaAs), germanium or other semiconductor material.

An MRAM memory cell comprises a magnetoresistive structure that stores a magnetic moment that is switched between two directions corresponding to two data states (“1” and “0”). In an MRAM cell, information is stored in magnetization directions of a free magnetic layer. In a spin-transfer MRAM memory cell, the data state is programmed to a “1” or to a “0” by forcing a write current directly through the stack of layers of materials that make up the MRAM cell. Generally speaking, the write current, which is spin polarized by passing through one layer, exerts a spin-torque on a subsequent free magnetic layer. The torque switches the magnetization of the free magnetic layer between two stable states depending upon the polarity of the write current.

### SUMMARY

Embodiments of the invention provide magnetoresistive structures.

In accordance with an embodiment of the invention, a magnetoresistive structure includes a ferromagnetic layer, a ferrimagnetic layer coupled to the ferromagnetic layer, a pinned layer and a nonmagnetic spacer layer. A free side of the magnetoresistive structure comprises the ferromagnetic layer and the ferrimagnetic layer. The nonmagnetic spacer layer is at least partly between the free side and the pinned layer. A saturation magnetization of the ferromagnetic layer opposes a saturation magnetization of the ferrimagnetic layer.

Other embodiments of the invention include a magnetoresistive memory device and an integrated circuit comprising the magnetoresistive structure. The magnetoresistive memory device stores at least two data states corresponding to at least two directions of a magnetic moment. The integrated circuit further includes a substrate on which the pinned layer, the nonmagnetic space layer, the ferromagnetic layer and the ferrimagnetic layer are formed.

The nonmagnetic spacer layer may include a tunnel barrier layer, such as one composed of magnesium oxide (MgO) and adapted to provide tunnel magnetoresistance, or a nonmagnetic metal layer adapted to provide giant magnetoresistance.

Advantageously, bilayers containing a ferromagnetic layer and a ferrimagnetic layer with compensating saturation magnetization (Mₛ) and high anisotropy field (Hₖ) form a free layer in magnetoresistive structures, for example, spin-torque-switched devices. Of further advantage are structures, devices, memories and methods of the invention adapted to changing the direction of a magnetic moment of the free ferromagnetic layer using less write current than write current required for a conventional spin-torque transfer magnetoresistive device. The magnetoresistive memory may be, for example, a magnetoresistive random access memory (MRAM) comprising an embodiment of the magnetoresistive device of the invention. The MRAM is adapted for writing data using less write current than write current required for a conventional spin-torque MRAM. Aspects of the invention provide, for example, for lower switching current in spin-torque switched nanostructures while keeping the nanomagnet stable against thermally activated reversal.

These and other features, objects and advantages of the present invention will become apparent from the following detailed description of illustrative embodiments thereof, which is to be read in connection with the accompanying drawings.

### BRIEF DESCRIPTION OF THE DRAWINGS

FIG. 1 is an exemplary graph of in-plane anisotropy and total energy as functions of net magnetization of a bilayer, according to an embodiment of the present invention.

FIG. 2 illustrates a spin-torque magnetoresistive structure.

FIG. 3 illustrates a spin-torque structure having a ferromagnetic layer abutting a tunnel barrier layer, according to an embodiment of the present invention.

FIG. 4 illustrates a spin-torque structure having a ferrimagnetic layer abutting a tunnel barrier layer, according to an embodiment of the present invention.

FIG. 5 illustrates writing a spin-torque structure, according to an embodiment of the present invention.

FIG. 6 illustrates a method for forming a spin-torque structure, according to an embodiment of the present invention.

FIG. 7 is a cross-sectional view depicting an exemplary packaged integrated circuit, according to an embodiment of the present invention.

### DETAILED DESCRIPTION

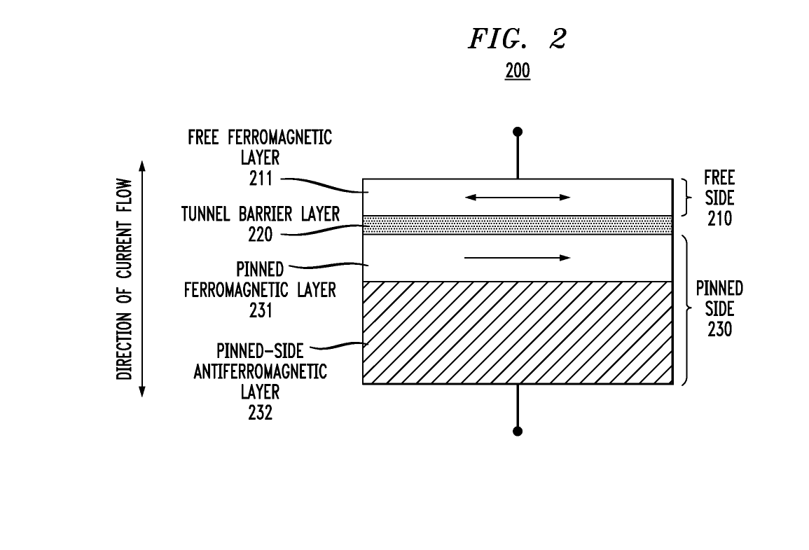

Embodiments of the invention will be described herein in the context of exemplary spin-torque switched devices and method for use therewith. It is to be understood, however, that embodiments of the invention are not limited to the devices and methods shown and described herein. Rather, embodiments of the invention are directed to techniques for reducing switching current in spin-torque switched devices. Although embodiments of the invention may be fabricated in or upon a silicon wafer, embodiments of the invention can alternatively be fabricated in or upon wafers comprising other materials, including but not limited to gallium arsenide (GaAs), indium phosphide (InP), etc. Although embodiments of the invention may be fabricated using the materials described below, alternate embodiments may be fabricated using other materials. The drawings are not drawn to scale. Thicknesses of various layers depicted by the drawings are not necessarily indicative of thicknesses of the layers of embodiments of the invention. For the purposes of clarity, some commonly used layers, well known in the art, have not been illustrated in the drawings of FIGS. 2-5, including, but not limited to, protective cap layers, seed layers, and an underlying substrate. The substrate may be a semiconductor substrate, such as silicon, or any other suitable structure.

Ferromagnetic materials exhibit parallel alignment of atomic magnetic moments resulting in relatively large net magnetization even in the absence of a magnetic field. The parallel alignment effect only occurs at temperatures below a certain critical temperature, called the Curie temperature. In ferromagnets, two nearby magnetic dipoles tend to align in the same direction because of the Pauli principle: two electrons with the same spin cannot also have the same “position”, which effectively reduces the energy of their electrostatic interaction compared to electrons with opposite spin.

The atomic magnetic moments in ferromagnetic materials exhibit very strong interactions produced by electronic exchange forces and result in a parallel or anti-parallel alignment of atomic magnetic moments. Exchange forces can be very large, for example, equivalent to a field on the order of 1000 Tesla. The exchange force is a quantum mechanical phenomenon due to the relative orientation of the spins of two electrons. The elements Fe, Ni, and Co and many of their alloys are typical ferromagnetic materials. Two distinct characteristics of ferromagnetic materials are their spontaneous magnetization and the existence of magnetic ordering temperatures (i.e., Curie temperatures). Even though electronic exchange forces in ferromagnets are very large, thermal energy eventually overcomes the exchange and produces a randomizing effect. This occurs at a particular temperature called the Curie temperature (Tₒ). Below the Curie temperature, the ferromagnet is ordered and above it, disordered. The saturation magnetization goes to zero at the Curie temperature.

Antiferromagnetic materials are materials having magnetic moments of atoms or molecules, usually related to the spins of electrons, align in a regular pattern with neighboring spins, on different sublattices, pointing in opposite directions. Generally, antiferromagnetic order may exist at sufficiently low temperatures, vanishing at and above a certain temperature, the Néel temperature. Above the Néel temperature, the material is typically paramagnetic. When no external magnetic field is applied, the antiferromagnetic material corresponds to a vanishing total magnetization. In a magnetic field, ferrimagnetic-like behavior may be displayed in the antiferromagnetic phase, with the absolute value of one of the sublattice magnetizations differing from that of the other sublattice, resulting in a nonzero net magnetization.

Antiferromagnets can couple to ferromagnets, for instance, through a mechanism known as exchange anisotropy (for, example, wherein an ferromagnetic film is either grown upon the antiferromagnet or annealed in an aligning magnetic field) causing the surface atoms of the ferromagnet to align with the surface atoms of the antiferromagnet. This provides the ability to pin the orientation of a ferromagnetic film. The temperature at or above which an antiferromagnetic layer loses its ability to pin the magnetization direction of an adjacent ferromagnetic layer is called the blocking temperature of that layer and is usually lower than the Néel temperature.

A ferrimagnetic material is a material in which the magnetic moments of the atoms on different sublattices are opposed. However, in ferrimagnetic materials, the opposing moments are unequal and a spontaneous magnetization remains. This happens when the sublattices consist of different materials or ions (e.g., Fe²⁺ and Fe³⁺). Ferrimagnetic materials are like ferromagnets in that they hold a spontaneous magnetization below the Curie temperature, and show no magnetic order (are paramagnetic) above this temperature. However, there is sometimes a temperature below the Curie temperature at which the two sublattices have equal moments, resulting in a net magnetic moment of zero; this is called the magnetization compensation point. For example, the magnetization compensation point is observed in garnets and rare earth—transition metal alloys (RE-TM). Ferrimagnets may also exhibit an angular momentum compensation point at which the angular momentum of the magnetic sublattices is compensated. Ferromagnetism is exhibited by, for example, magnetic garnets, magnetite (iron (II,III) oxide; Fe₃O₄), YIG (yttrium iron garnet) and ferrites composed of iron oxides and other elements such as aluminum, cobalt, nickel, manganese and zinc.

Saturation magnetization (Mₛ) of a magnetic material is the magnetic field of the magnetic material wherein an increase in an externally applied magnetic field H does not significantly increase the magnetization (i.e., magnetic field B of the magnetic material) of the magnetic material further, so the total magnetic field B of the magnetic material levels off. Saturation magnetization is a characteristic particularly of ferromagnetic materials. In fact, above saturation, the magnetic field B continues increasing, but at the paramagnetic rate, which can be, for example, 3 orders of magnitude smaller than the ferromagnetic rate seen below saturation. The relation between the externally applied magnetizing field H and the magnetic field B of the magnetic material can also be expressed as the magnetic permeability: μ=B/H. The permeability of ferromagnetic materials is not constant, but depends on H. In saturable materials the permeability typically increases with H to a maximum, then as it approaches saturation inverts and decreases toward zero.

Magnetic anisotropy is the direction dependence of magnetic properties of a material. A magnetically isotropic material has no preferential direction for a magnetic moment of the material in a zero magnetic field, while a magnetically anisotropic material will tend to align its moment to an easy axis. There are different sources of magnetic anisotropy, for example: magnetocrystalline anisotropy, wherein the atomic structure of a crystal introduces preferential directions for the magnetization; shape anisotropy, when a particle is not perfectly spherical, the demagnetizing field will not be equal for all directions, creating one or more easy axes; stress anisotropy, wherein tension may alter magnetic behavior, leading to magnetic anisotropy; and exchange anisotropy that occurs when antiferromagnetic and ferromagnetic materials interact. The Anisotropy field (Hₖ) may be defined as the weakest magnetic field which is capable of switching the magnetization of the material from the easy axis.

Giant magnetoresistance (GMR) is a quantum mechanical magnetoresistance effect observed in certain structures, for example, structures comprising two magnetic layers (e.g. ferromagnetic or ferrimagnetic layers) with a nonmagnetic layer between the two magnetic layers. The magnetoresistance effect manifests itself as a significantly lower electrical resistance of the nonmagnetic layer, due to relatively little magnetic scattering, when the magnetizations of the two magnetic layers are parallel. The magnetizations of the two magnetic layers may be made parallel by, for example, placing the structure within an external magnetic field. The magnetoresistance effect further manifests itself as a significantly higher electrical resistance of the nonmagnetic layer, due to relatively high magnetic scattering, when the magnetizations of the two magnetic layers are anti-parallel. Because of an antiferromagnetic coupling between the two magnetic layers, the magnetizations of the two magnetic layers are anti-parallel when the structure is not at least partially within an external magnetic field.

The term nonmagnetic metal, as used herein, means a metal that is not magnetic including not ferromagnetic and not antiferromagnetic.

Tunnel magnetoresistance (TMR) is a magnetoresistive effect that occurs in magnetic tunnel junctions (MTJs). A MTJ is a component consisting of two magnets separated by a thin insulator. If the insulating layer is thin enough (typically a few nanometers), electrons can tunnel from one magnet into the other. Since this process is forbidden in classical physics, TMR is a strictly quantum mechanical phenomenon.

The Curie temperature of a ferromagnetic material is the temperature above which it loses its characteristic ferromagnetic ability (e.g., 768° C. for iron). At temperatures below the Curie temperature, the magnetic moments are at least partially aligned within magnetic domains in ferromagnetic materials. As the temperature is increased towards the Curie temperature, the alignment (magnetization) within each domain decreases. Above the Curie temperature, the material is purely paramagnetic and there are no magnetized domains of aligned moments.

The term proximate or proximate to, as used herein, has meaning inclusive of, but not limited to, abutting, in contact with, and operatively in contact with. In particular and with respect to magnetic coupling, proximate or proximate to includes, but is not limited to, being operatively magnetically coupled. The term abut(s) or abutting, as used herein, has meaning that includes, but is not limited to, being proximate to.

It is a challenge to grow single materials having both low Mₛ and high Hₖ (see: J. Z. Sun, Spin Angular Momentum Transfer in Current-Perpendicular Nanomagnetic Junctions, IBM Journal of Research and Development, volume 50, no. 1, January 2006, pages 81-100; the disclosure of which is incorporated herein by reference).

According to principles of the invention, using free layer materials with low saturation magnetization (Mₛ) and high anisotropy field (Hₖ) is a way to lower the switching current in spin-torque-switched nanostructures. Low Mₛ and high Hₖ can be achieved simultaneously in certain bilayer structures that contain exchange coupled ferromagnetic and ferrimagnetic layers. The key requirement on the materials is that the magnetic moments from the coupled ferromagnetic and ferrimagnetic layers cancel each other, rather than add to each other. A bilayer comprising a ferromagnetic layer of iron (Fe) and a ferrimagnetic layer of an alloy of cobalt (Co) and gadolinium (Gd) (e.g., Fe|CoGd), and a bilayer comprising a ferromagnetic layer of an alloy of Co, Fe and Boron (B) and a ferrimagnetic layer of an alloy of Co and Gd (e.g., CoFeB|CoGd) are examples of these certain bilayer structures having both low Mₛ and high Hₖ.

The CoGd layer is ferrimagnetic, where the magnetic moment of the Co and Gd sub-lattices are aligned anti-parallel, i.e., the total saturation magnetization for CoGd ferrimagnetic layer is given by Mₛ_{_{—}}ₜₒₜ=Mₛ_{_{—}}_{Co}−Mₛ_{_{—}}_{Gd}; where Mₛ_{_{—}}ₜₒₜ is the total saturation magnetization, Mₛ_{_{—}}_{Co} is the saturation magnetization of Co, and Mₛ_{_{—}}_{Gd} is the saturation magnetization of Gd. At room temperature, as the Co content of the CoGd ferrimagnetic layer approaches about 80%, the net magnetization of the CoGd ferrimagnetic layer approaches and gets close to zero, wherein the magnetic moments from the Co and Gd sub-lattices cancel each other nearly completely. When the Co content is more than about 80%, the Mₛ_{_{—}}_{Co} dominates the total magnetic moment of the CoGd ferrimagnetic layer. When the Co content is less than about 80%, the Mₛ_{_{—}}_{Gd} dominates the total magnetic moment of the CoGd ferrimagnetic layer. For one embodiment of the invention, the CoGd composition is approximately 60% Co and approximately 40% Gd (60Co40Gd), and the Gd magnetic moment dominates the total magnetic moment. In the CoFeB|CoGd or Fe|CoGd bilayer embodiments of the invention, the Fe or CoFeB magnetic moment of the Fe or CoFeB ferromagnetic layers, respectively, is parallel exchange coupled to magnetic moment of the Co sub-lattice in the CoGd ferrimagnetic layer. Thus, the net magnetization of the bilayer can be adjusted over a wide range by varying the thickness combination of the ferromagnetic layer and the ferrimagnetic layer, or by changing the composition of the ferrimagnetic layer. The bilayer compensation point is a point at which the magnet moments from the two layers within the bilayer completely cancel each other. The bilayer composition and/or the layer thicknesses can be varied to adjust the bilayer compensation point.

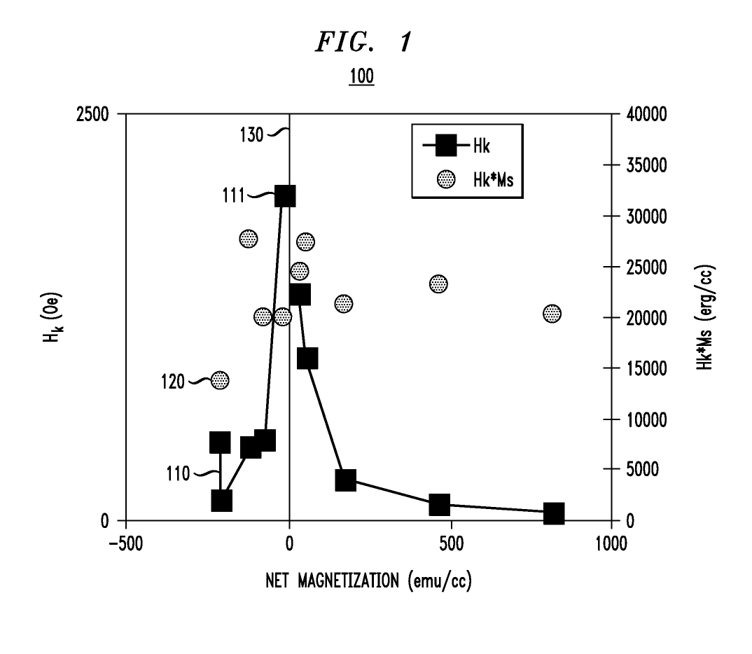

FIG. 1 is an exemplary graph 100 of the in-plane anisotropy 110 and the total energy 120 as a function of the net magnetization of the bilayer, according to an embodiment of the invention. When the net magnetization goes through the bilayer compensation point (indicated by line 130 intersecting the horizontal axis at the point of zero magnetization), a large increase in the in-plane anisotropy field (Hₖ) of the bilayer is observed (see Hₖ point 111), while the total energy (Mₛ*Hₖ) keeps more or less constant. Films with compositions close to the bilayer compensation point are of interest because of their low magnetic moments and high anisotropy fields.

The CoFeB|CoGd and Fe|CoGd bilayers have good materials compatibility with a tunnel barrier comprising magnesium oxide (MgO). An MgO tunnel barrier is used in many spin-torque-switched tunnel devices. For example, a MTJ structure with a free bilayer comprising a 7 Å thick CoFeB layer and an 90 Å thick CoGd layer (7 Å CoFeB|90 Å CoGd) shows over 50% TMR effect (i.e., change in the resistance of the MTJ of over 50%) after a 240 degrees Celsius (C), 2 hour anneal, when the TMR is measured by a current-in-plane-tunneling method. The TMR of an MTJ structure strongly depends on the Fe or CoFeB ferromagnetic layer thickness, the CoGd ferrimagnetic layer thickness, the MgO barrier thickness and the anneal temperature. In addition, the junction resistance-area product (RA) was measured to be more sensitive to the post deposition annealing than other MTJs with other CoFeB free layers, indicating that there is a fine balance between the oxidation of the MgO barrier and the integrity of the CoGd-containing free layer. In summary, CoFeB|CoGd and Fe|CoGd bilayers can be used as free layers in spin-torque-switched devices.

A spin-torque transfer magnetoresistive structure or spin-torque magnetoresistive random access memory (MRAM) may comprise a two-terminal device 200 shown in FIG. 2 comprising, in a MTJ, a free side 210 comprising a free ferromagnetic layer 211, tunnel barrier layer 220, and pinned side 230 comprising a pinned ferromagnetic layer 231 and a pinned-side antiferromagnetic layer 232. A tunnel junction comprises the tunnel barrier layer 220 between the free side 210 and the pinned side 230. The direction of the magnetic moment of the pinned ferromagnetic layer 231 is fixed in direction (e.g., pointing to the right) by the pinned-side antiferromagnetic layer 232. A current passed down through the tunnel junction makes magnetization of the free ferromagnetic layer 211 parallel to the magnetization of the pinned ferromagnetic layer 231, e.g., pointing to the right (down is in the vertical direction from the top to the bottom of FIG. 2). A current passed up through the tunnel junction makes the magnetization of the free ferromagnetic layer 211 anti-parallel to the magnetization of the pinned ferromagnetic layer 231, e.g., pointing to the left. A smaller current through the device 200, passing up or passing down, is used to read the resistance of the device 200, which depends on the relative orientations of the magnetizations of the free ferromagnetic layer 211 and the pinned ferromagnetic layer 231.

Conventional spin-torque MRAM has several issues. One issue is the need to reduce write current needed to switch the MRAM cells. Principles of the current invention solve this problem by incorporating a bilayer comprising a ferromagnetic layer and a ferromagnetic layer into the free layer.

A spin-torque device, according to an embodiment of the invention, comprises a free side, a nonmagnetic spacer layer and a pinned side. The free side comprises at least two layers. The pinned side may comprise a single layer or multiple layers. The nonmagnetic spacer layer may comprise a tunnel barrier layer (TMJ device) or a nonmagnetic metallic layer (GMR device). The tunnel barrier layer comprises an electrically insulating material through which electrons tunnel when the tunnel barrier layer is appropriately biased with voltage and magnetization. The nonmagnetic metallic layer comprises an electrically conductive nonmagnetic metal layer. When reading the state of the either the TMR device or the GMR device, the output signal is generated from the magnetoresistance signals across the nonmagnetic spacer layer. The magnetoresistance signal is due to tunneling magnetoresistance if the nonmagnetic spacer is the tunnel barrier layer (TMR device) or to giant magnetoresistance if the spacer is the metallic layer (GMR device).

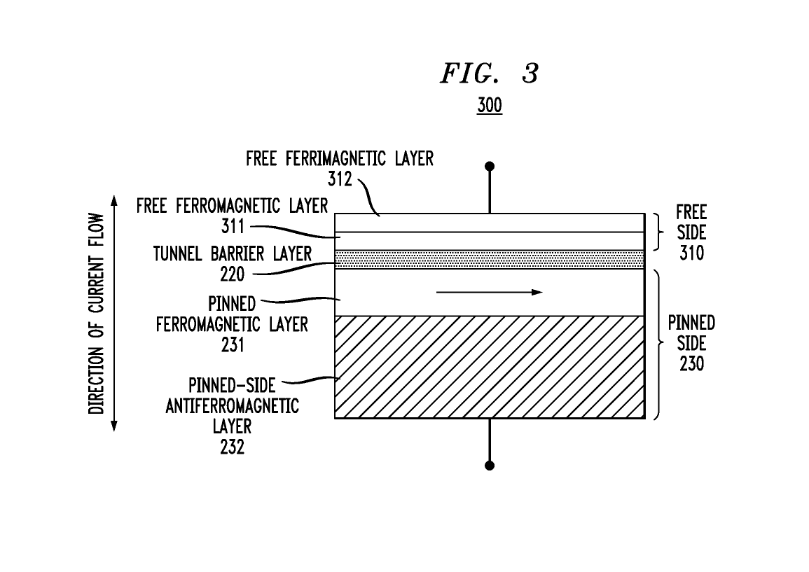

As illustrated in FIG. 3, a spin-torque structure 300, according to an embodiment of the invention, comprises a free side 310, a pinned side 230 and a tunnel barrier layer 220. The free side 310 comprises a relatively thin free bilayer comprising a free ferromagnetic layer 311 abutting and exchange coupled to a free ferrimagnetic layer 312. The free side 310 abuts the tunnel barrier layer 220. Specifically, the free ferromagnetic layer 311 abuts the tunnel barrier layer 220. The tunnel junction 220 abuts the pinned side 230.

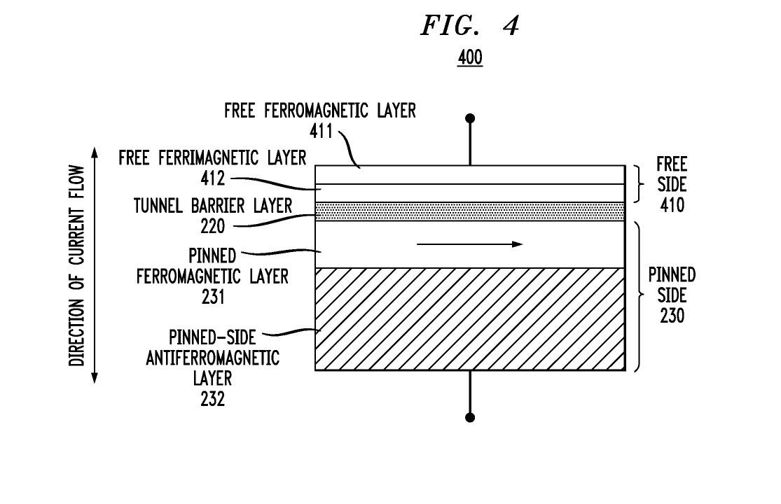

FIG. 4 illustrates an alternate spin-torque structure 400, according to an alternate embodiment of the invention. This alternate spin-torque structure 400 is similar to the spin-torque structure 300 except that the placement of the free ferromagnetic layer and the free ferrimagnetic layers are interchanged. Alternate spin-torque structure 400 comprises a free side 410, a pinned side 230 and a tunnel barrier layer 220. The free side 410 comprises a relatively thin free bilayer comprising a free ferrimagnetic layer 412 abutting and exchange coupled to a free ferromagnetic layer 411. The free side 410 abuts the tunnel barrier layer 220. Specifically, the free ferrimagnetic layer 412 abuts the tunnel barrier layer 220. The tunnel junction 220 abuts the pinned side 230.

The tunnel barrier layer 220 may comprise, for example, magnesium oxide (MgO). In the embodiments shown in FIGS. 3 and 4, the tunnel barrier layer 220 is an example of a nonmagnetic spacer layer. Other embodiments, having a magnetoresistance signal due to giant magnetoresistance, may include a nonmagnetic metallic layer as a nonmagnetic spacer layer in place of the tunnel barrier layer. Embodiments comprising the nonmagnetic metallic layer operate, for example, during reading or writing, in a similar way as embodiments comprising the tunnel barrier layer, although the underlying physics of the magnetoresistances differ between the tunnel barrier layer (tunneling magnetoresistance) and the nonmagnetic metallic layer (giant magnetoresistance). The nonmagnetic metallic layer may comprise, for example, Cu, Au, or Ru.

A spin-torque device, such as an MRAM memory or MRAM memory cell, according to an embodiment of the invention comprises, for example, the spin-torque structure 300 or the alternate spin-torque structure 400. An MRAM, comprising one or more of the MRAM memory cells, may further comprise other electronic devices or structures such as electronic devices comprising silicon, a transistor, a field-effect transistor, a bipolar transistor, a metal-oxide-semiconductor transistor, a diode, a resistor, a capacitor, an inductor, another memory device, interconnect, an analog circuit and a digital circuit. Data stored within the MRAM memory cell corresponds to the direction of a magnetic moment in the free ferromagnetic layer and/or the free ferrimagnetic layer.

In the embodiments of FIGS. 3 and 4, the pinned side 230 comprises a pinned ferromagnetic layer 231 and a pinned-side antiferromagnetic layer 232 abutting and exchange coupled to the pinned ferromagnetic layer 231. Although the pinned side 230 comprises the layers shown in FIGS. 3 and 4, the invention is not so limited; other arrangements of the pinned side 230 are known in the art and may be used in other embodiments of the invention.

The pinned ferromagnetic layer 231 may comprise, for example, an anti-parallel (AP) layer comprising a 2 nanometer (nm) thick layer comprising a first alloy of cobalt and iron (CoFe), a 0.8 nm ruthenium (Ru) layer, and another 2 nm thick layer comprising a second alloy of cobalt and iron (CoFe). Alternately, the pinned ferromagnetic layer 231 may comprise a simple pinned layer, for example, a 3 nm thick layer of an alloy of cobalt and iron (CoFe).

The pinned-side antiferromagnetic layer 232 is strongly exchange coupled to the pinned ferromagnetic layer 231 pinning the pinned ferromagnetic layer 231. The pinned-side antiferromagnetic layer 232 is used to pin the pinned ferromagnetic layer 231 to a particular alignment.

The pinned-side antiferromagnetic layer 232 may comprise, for example, an alloy of manganese (Mn) such as an alloy comprising iridium and manganese (IrMn), an alloy comprising platinum and manganese (PtMn), an alloy comprising iron and manganese (FeMn), or an alloy comprising nickel and manganese (NiMn). Alternately, the pinned-side antiferromagnetic layer 232 may comprises different antiferromagnetic materials.

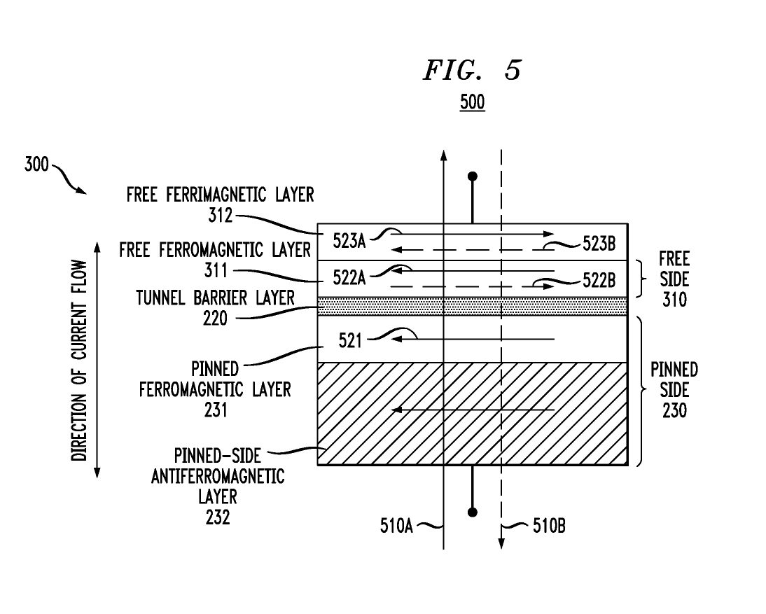

FIG. 5 shows the write operation of the spin-torque structure 500. The spin-torque structure 500 comprised the spin-torque structure 300 with a write current applied. Writing, in one case, is accomplished by an upwards write current 510A, comprising a flow of electrons driven vertically through the spin-torque structure 500. The direction of the arrows on the heavy vertical lines points in the direction of electron flow. To change the data state of the spin-torque structure 500, the write current switches the magnetic moment of the free ferromagnetic layer 311. Because the free ferrimagnet layer is strongly exchange coupled to the free ferromagnetic layer, the magnetic moment of the free ferrimagnetic layer 312 is also switched. If a magnetic moment 521 of the pinned ferromagnetic layer 231 points, for example, to the left, the electrons flowing within the upwards current 510A will be spin-polarized to the left and therefore place a torque on the free ferromagnetic layer 311 to switch a magnetic moment 522A of the free ferromagnetic layer 311 to the left. Correspondingly, a magnetic moment 523A of the free ferrimagnetic layer 312 will be switched to the right. If the data state already corresponded to the data state that otherwise would be induced by the upwards write current 510A, the magnetic moment 522A of the free ferromagnetic layer 311 and the magnetic moment 523A of the free ferrimagnetic layer 312 were already set to the left and right, respectively, and will not be switched by the upwards write current 510A.

Conversely, if the flow of electrons is in the opposite direction (downward) as in the downward write current 510B, the electrons will be spin-polarized to the right, and a magnetic moment 522B of the free ferromagnetic layer 311 will be switched to the right when changing the data state. Consequently, a magnetic moment 523B of the free ferrimagnetic layer 312 will be switched to the left. If the data state already corresponded to the data state that otherwise would be induced by the downward write current 510B, the magnetic moment 522B of the free ferromagnetic layer 311 and the magnetic moment 523B of the free ferrimagnetic layer 312 were already set to the right and left, respectively, and will not be switched by the downwards write current 510B.

The direction of the magnetic moment 521 of the pinned ferromagnetic layer 231, for example, is set using a high-temperature anneal in an applied magnetic field.

Consider reading the spin-torque structure 300. In one embodiment, a read current, less than the write current, is applied to read the resistance of the tunnel barrier layer 220. The read current is applied across the spin-torque structure 300 to flow through the spin-torque structure 300 from top to bottom or from bottom to top. The resistance of the tunnel barrier layer 220 depends on the relative magnetic orientation (direction of magnetic moment) of the free ferromagnetic layer 311. If the magnetic orientations are parallel, the resistance of the tunnel barrier layer 220 is relatively low. If the magnetic orientations are anti-parallel, the resistance of the tunnel barrier layer 220 is relatively high. As previously stated, the resistance of the tunnel barrier layer 220 is due to tunneling magnetoresistance, and the resistance of a nonmagnetic metal layer that may be used as a nonmagnetic spacer layer in place of the tunnel barrier layer 220 is due to giant magnetoresistance. Measuring the voltage across the spin-torque structure 300, corresponding to the applied read current, allows for calculation of the resistance across the spin-torque structure 300 according to ohms law. Because the resistance of the tunnel barrier layer 220 dominates the series resistance of the layers within the spin-torque structure 300, the resistance of the tunnel barrier layer 220 is obtained, to some degree of accuracy, by measuring the resistance of the spin-torque structure 300. In an alternate method of reading, a read voltage is applied across the spin-torque structure 300 and a current is measured from which the resistance of the spin-torque structure 300 is calculated.

Read and write operations of the alternate spin-torque structure 400 are similar to the read and write operations described above for the spin-torque structure 300, except that, in the alternate spin-torque structure 400, it is the ferrimagnetic layer 412 that functions in place of the ferromagnetic layer 311 in spin-torque structure 300. In changing the data state, the ferrimagnetic layer 412 is affected directly by electrons flowing within the write current. The electrons within the write current will place a torque on the free ferrimagnetic layer 412 to switch a magnetic moment of the free ferrimagnetic layer 412. The magnetic moment of the free ferromagnetic layer 411 will switch as a consequence of being strongly exchange coupled to the free ferrimagnetic layer 412. In reading, the magnetoresistance of the tunnel barrier layer will be determined by the relative orientations of the free ferrimagnetic layer 412 and the pinned side layer abutting the tunnel barrier layer (e.g., the pinned ferrimagnetic layer).

FIG. 6 illustrates a method 600 for forming a spin-torque structure, according to an embodiment of the invention. For example, the spin-torque structure comprises the spin-torque structure 300, the alternate spin-torque structure 400 or an MRAM memory cell. The steps of method 600 may occur in orders other than that illustrated.

The first step 610 comprises forming a pinned-side antiferromagnetic layer, for example the pinned-side antiferromagnetic layer 232.

The second step 620 comprises forming a pinned ferromagnetic layer, for example the pinned ferromagnetic layer 231. The pinned-side antiferromagnetic layer is exchange coupled and abutting the pinned ferromagnetic layer.

The third step 630 comprises forming a tunnel barrier layer. For example, the tunnel barrier layer comprises the tunnel barrier layer 220. The tunnel barrier layer abuts the pinned ferromagnetic layer.

The fourth step 640 comprises forming a free ferromagnetic layer, for example, the free ferromagnetic layer 311. The free ferromagnetic layer abuts the tunnel barrier layer.

The fifth step 650 comprises forming a free ferrimagnetic layer, for example, the free ferrimagnetic layer 312. The free ferrimagnetic layer is exchange coupled to and abuts the free ferromagnetic layer.

According to an alternate method, the third step 630 comprises forming a nonmagnetic metal layer instead of the tunnel barrier layer, wherein the pinned ferromagnetic and the free ferromagnetic layers abut the nonmagnetic metal layer.

According to another alternate method, the layers are formed such that the free ferrimagnetic layer abuts the tunnel barrier layer instead of the free ferromagnetic layer abutting the tunnel barrier layer.

In according to yet another alternate method, the first step (610) and the second step (620) are replaced by an alternate step of forming a pinned side which may comprise one or more layers different from the combination of the pinned-side antiferromagnetic layer 232 and the pinned ferromagnetic layer 231.

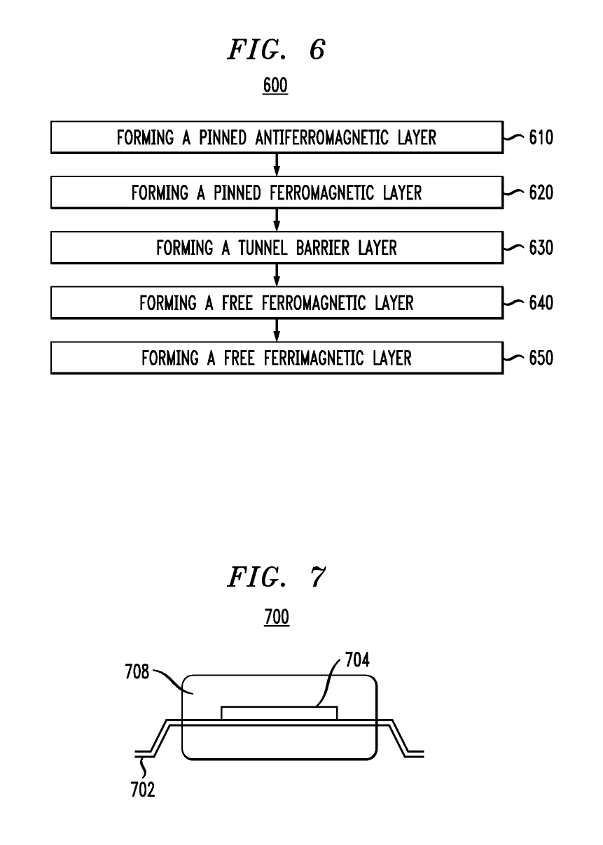

FIG. 7 is a cross-sectional view depicting an exemplary packaged integrated circuit 700 according to an embodiment of the present invention. The packaged integrated circuit 700 comprises a leadframe 702, a die 704 attached to the leadframe, and a plastic encapsulation mold 708. Although FIG. 7 shows only one type of integrated circuit package, the invention is not so limited; embodiments of the invention may comprise an integrated circuit die enclosed in any package type.

The die 704 includes a structure described herein according to embodiments of the invention and may include other structures or circuits. For example, the die 704 includes at least one spin-torque structure or MRAM according to embodiments of the invention, for example, the spin-torque structures 300, 400 and 500 or embodiments formed according to the method of the invention (e.g., the method of FIG. 6). For example, the other structures or circuits may comprise electronic devices comprising silicon, a transistor, a field-effect transistor, a bipolar transistor, a metal-oxide-semiconductor transistor, a diode, a resistor, a capacitor, an inductor, another memory device, interconnect, an analog circuit and a digital circuit. The spin torque structure or MRAM may be formed upon or within a semiconductor substrate, the die also comprising the substrate.

An integrated circuit in accordance with the present invention can be employed in applications, hardware and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of this invention. Given the teachings of the invention provided herein, one of ordinary skill in the art will be able to contemplate other implementations and applications of the techniques of the invention.

Although illustrative embodiments of the invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A method for forming a magnetoresistive structure, the method comprising the steps of:
forming a ferromagnetic layer;
forming a ferrimagnetic layer coupled to the ferromagnetic layer, wherein a free side of the magnetoresistive structure comprises the ferromagnetic layer and the ferrimagnetic layer;
forming a pinned layer; and
forming a nonmagnetic spacer layer at least partly between the free side and the pinned layer;
wherein a saturation magnetization of the ferromagnetic layer opposes a saturation magnetization of the ferrimagnetic layer.

2. The method of claim 1, wherein the nonmagnetic spacer layer comprises at least one of: (i) a tunnel barrier layer adapted to provide tunnel magnetoresistance, (ii) a tunnel barrier layer comprising magnesium oxide (MgO) and adapted to provide tunnel magnetoresistance, and (iii) a nonmagnetic metal layer adapted to provide giant magnetoresistance.

3. The method of claim 1, wherein the ferrimagnetic layer comprises a first material comprises cobalt (Co) and a second material comprises gadolinium (Gd).
